(19) United States
(12) Patent Application Publication
(10) Pub. No.: US 2001/0052641 A1
(43) Pub. Date: Dec. 20, 2001

(54) Power semiconductor device

(76) Inventors: Frank Kuo, Kaohsiung City (TW); Hamza Yilmaz, Santa Clara, CA (US); Mohammed Kasem, Santa Clara, CA (US); Oscar Ou, Kaohsiung City (TW); Sen Mao, Kaohsiung City (TW); Sam Kuo, Kaohsiung City (TW)

Correspondence Address: KNOBBE MARTENS OLSON & BEAR LLP, 620 NEWPORT CENTER DRIVE, SIXTEENTH FLOOR, NEWPORT BEACH, CA, 92660, US

(21) Appl. No.: 09/879,531

(22) Filed: Jun. 12, 2001

(30) Foreign Application Priority Data
Jun. 15, 2000 (TW) 089210245

(51) Int. Cl. H01L 23/02

(52) U.S. Cl. 257/686; 257/723; 257/725; 257/777

(57) ABSTRACT

A power semiconductor device includes upper and lower dice that have source, drain and gate contacts, a first metal sheet sandwiched by the upper and lower dice and having source and gate terminals connected to the source and gate contacts of the upper and lower dice, and upper and lower second metal sheets sandwiching assembly of the upper and lower dice and the first metal sheet and respectively having drain terminals that are connected to the drain contacts of the upper and lower dice and that are coupled to each other.

### BACKGROUND OF THE INVENTION

1. Field of the Invention

This invention relates to a power semiconductor device, more particularly to a power semiconductor device including a pair of dice encapsulated in a single package.

2. Description of the Related Art

FIG. 1 illustrates a conventional power semiconductor device 1. The power semiconductor device 1 includes a semiconductor die 11, which has a bottom surface defining a drain contact (not shown), and a top surface that includes a first metallized region defining a source contact 111 and a second metallized region defining a gate contact 112. The power semiconductor device 1 further includes a bottom metal plate 121 coupled to and electrically connected to the drain contact, a plurality of drain terminals 122 extending outwardly from the bottom metal plate 121 and electrically connected to the drain contact, a plurality of spaced apart source terminals 123 electrically connected to the source contact 111 via a plurality of gold wires 125, and a gate terminal 124 electrically connected to the gate contact 112 via a gold wire 125. Assembly of the die 11, the bottom metal plate 121, the drain, source and gate terminals 122, 123, 124, and the gold wires 125 is encapsulated with a plastic encapsulant 13 while leaving distal ends of the drain, source and gate terminals 122, 123, 124 exposed to form the power semiconductor device 1.

The aforesaid power semiconductor device 1 is disadvantageous in that in order to reduce the electrical resistance from the source contact 111 to the source terminals 123, a large number of the gold wires 125 are required to be employed in the power semiconductor device 1. Since the gold wires 125 are very expensive and can only be stitch bonded to the source contact 111 and the source terminal 123 one at a time, such number of the gold wires 125 will increase the production cost and the manufacturing time considerably. In addition, when additional dice 11 are to be encapsulated in a single package of the power semiconductor device 1, due to limitation of the wire bonding technique, the sole way of achieving this is to increase the size of the bottom metal plate 121 to accommodate the additional dice 11, thereby resulting in an enormous increase in the size of the power semiconductor device 1.

### SUMMARY OF THE INVENTION

Therefore, the object of the present invention is to provide a power semiconductor device that is capable of overcoming the aforementioned problems.

According to the present invention, a power semiconductor device comprises: an upper die that has a top surface defining a drain contact, and a bottom surface which includes a first metallized region defining a source contact, and a second metallized region defining a gate contact; a lower die that has a bottom surface defining a drain contact, and a top surface which includes a first metallized region defining a source contact, and a second metallized region defining a gate contact; a first metal sheet sandwiched by the bottom surface of the upper die and the top surface of the lower die, and having spaced apart source and gate terminals projecting laterally of the upper and lower dice and interconnecting electrically and respectively the source and gate contacts of the upper and lower dice; and a pair of upper and lower second metal sheets sandwiching assembly of the upper and lower dice and the first metal sheet, and respectively having drain terminals that project laterally of the upper and lower dice, that are connected electrically and respectively to the drain contacts of the upper and lower dice, and that are coupled to each other.

### BRIEF DESCRIPTION OF THE DRAWINGS

In drawings which illustrate an embodiment of the invention,

FIG. 1 is a schematic top view of a conventional power semiconductor device;

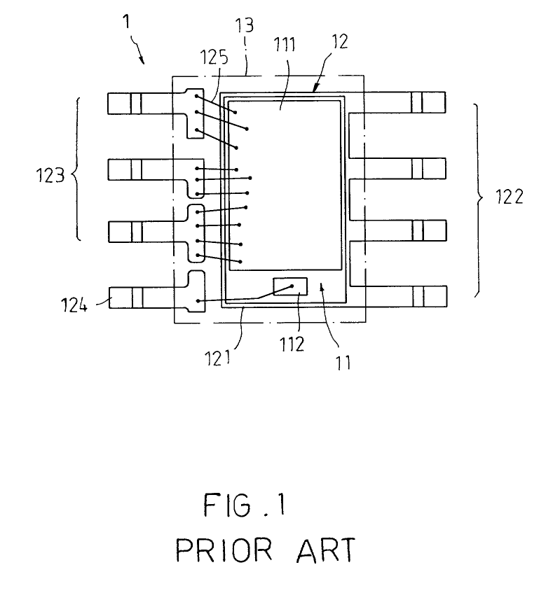

FIG. 2 is an exploded perspective view of a power semiconductor device embodying this invention; and

FIG. 3 is a schematic cross-sectional view of the power semiconductor device of FIG. 2.

### DETAILED DESCRIPTION OF THE PREFERRED EMBODIMENT

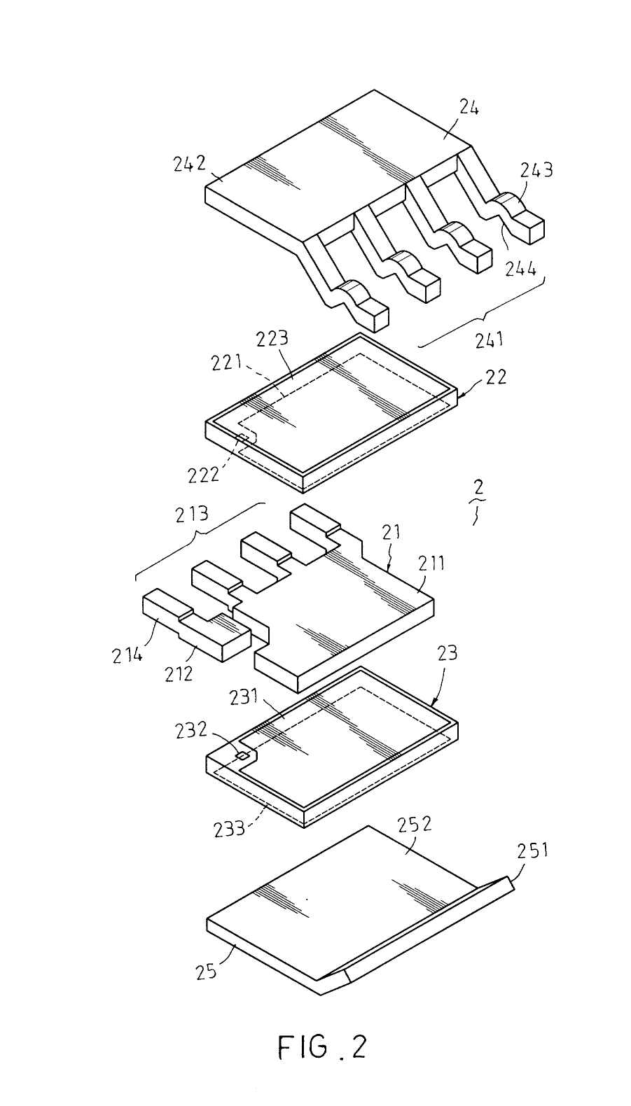

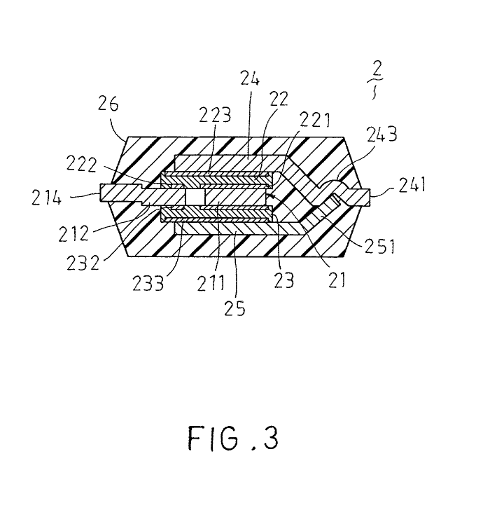

FIGS. 2 and 3 illustrate a power semiconductor device 2 embodying this invention. The power semiconductor device 2 includes upper and lower dice 22, 23, a first metal sheet 21, and upper and lower second metal sheets 24, 25, which are aligned vertically and which are encapsulated by a plastic encapsulant 26.

The upper die 22 has a top surface defining a drain contact 223, and a bottom surface which includes a first metallized region defining a source contact 221, and a second metallized region defining a gate contact 222.

The lower die 23 has a bottom surface defining a drain contact 233, and a top surface which includes a first metallized region defining a source contact 231, and a second metallized region defining a gate contact 232.

The first metal sheet 21 is comb-shaped, and is sandwiched by the bottom surface of the upper die 22 and the top surface of the lower die 23. The first metal sheet 21 has a source block portion 211 in contact with the source contact 221 of the upper die 22 at an upper side thereof and the source contact 231 of the lower die 23 at a lower side thereof, and a gate block portion 212 in contact with the gate contact 222 of the upper die 22 at an upper side thereof and the gate contact 232 of the lower die 23 at a lower side thereof. The first metal sheet 21 further has spaced apart source and gate terminals 213, 214 projecting laterally of the upper and lower dice 22, 23 and respectively from the source and gate block portions 211, 212 at one side thereof. Assembly of the upper and lower dice 22, 23, and the first metal sheet 21 is further sandwiched by the upper and lower second metal sheets 24, 25.

The upper second metal sheet 24 is comb-shaped, and has a drain block portion 242 in contact with the drain contact 223 of the upper die 22, and a plurality of drain terminals 241 that project downwardly and inclinedly from the drain block portion 242. Each drain terminal 241 of the upper second metal sheet 24 has a substantially V-shaped segment 243 that defines a downwardly opening V-shaped groove 244.

The lower second metal sheet 25 has a drain block portion 252 in contact with the drain contact 233 of the lower die 23, and a drain terminal 251 that projects upwardly and inclinedly from the drain block portion 252, and that has a distal end extending into the V-shaped groove 244 for coupling with the drain terminals 241 of the upper second metal sheet 24.

The plastic encapsulant 26 encloses assembly of the upper and lower dice 22, 23, the first metal sheet 21, and the upper and lower second metal sheets 24, 25, while leaving distal ends of the source and gate terminals 213, 214 of the first metal sheet 21, and the drain terminals 241 of the upper second metal sheet 24 exposed.

With the first metal sheet 21 and the upper and lower second metal sheet 24, 25 as bonding medium, and with the vertical alignment design of the assembly of the first metal sheet 21, the upper and lower second metal sheet 24, 25, and the upper and lower dice 22, 23, the problems, i.e., the labor-intensive and the expensive cost for the wire bonding and the tremendous increase in the size of the power semiconductor device for accommodating additional dice, that are associated with the prior art can be eliminated. Moreover, the electrical resistance from the source contact 221 of the upper die 22 to the source terminals 213 of the first metal sheet 21 and the electrical resistance from the source contact 231 of the lower die 23 to the source terminals 213 of the first metal sheet 21 are greatly reduced because a much larger contact area between the first metal sheet 21 and the upper and lower dice 22, 23 is provided for the power semiconductor device of this invention than that between the gold wires and the source contact of the die of the prior art.

With the invention thus explained, it is apparent that various modifications and variations can be made without departing from the spirit of the present invention. It is therefore intended that the invention be limited only as recited in the appended claims.

We claim:

1. A power semiconductor device, comprising:
an upper die that has a top surface defining a drain contact, and a bottom surface which includes a first metallized region defining a source contact, and a second metallized region defining a gate contact;
a lower die that has a bottom surface defining a drain contact, and a top surface which includes a first metallized region defining a source contact, and a second metallized region defining a gate contact;
a first metal sheet sandwiched by said bottom surface of said upper die and said top surface of said lower die, and having spaced apart source and gate terminals projecting laterally of said upper and lower dice and interconnecting electrically and respectively said source and gate contacts of said upper and lower dice; and
a pair of upper and lower second metal sheets sandwiching assembly of said upper and lower dice and said first metal sheet, and respectively having drain terminals that project laterally of said upper and lower dice, that are connected electrically and respectively to said drain contacts of said upper and lower dice, and that are coupled to each other.

2. The power semiconductor device of claim 1, wherein said drain terminal of said upper second metal sheet extends downwardly and inclinedly from said top surface of said upper die, and has a V-shaped segment that defines a downwardly opening V-shaped groove, said drain terminal of said lower second metal sheet extending upwardly and inclinedly from said bottom surface of said lower die, and into said V-shaped groove for coupling with said drain terminal of said upper second metal sheet.

3. The power semiconductor device of claim 1, further comprising a plastic encapsulant that encloses assembly of said upper and lower dice, said first metal sheet, and said upper and lower second metal sheets while leaving distal ends of said source and gate terminals of said first metal sheet, and said drain terminal of said upper second metal sheet exposed.
